(19) United States
(12) Patent Application Publication
(10) Pub. No.: US 2010/0255422 A1
(43) Pub. Date: Oct. 7, 2010

(54) MANUFACTURING METHOD OF LIQUID DISCHARGE HEAD

(75) Inventors: Kazunari Ishizuka, Suntou-gun (JP); Masako Shimomura, Yokohama-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/732,253

(22) Filed: Mar. 26, 2010

(30) Foreign Application Priority Data
Apr. 2, 2009 (JP) 2009-090117

(51) Int. Cl. G03F 7/20

(52) U.S. Cl. 430/312

(57) ABSTRACT

A manufacturing method of a liquid discharge head having a liquid flow path which communicates with a discharge port for discharging liquid, includes: providing a first layer made of a first photosensitive resin on a substrate; forming a mold of the flow path from the first layer by exposing a part of the first layer and developing the first layer; applying a light absorbent to a surface of the mold; providing a second layer made of a second photosensitive resin to coat the mold applied with the light absorbent; forming an opening that is to be the discharge port in the second layer by exposing a part of the second layer with light having a wavelength that can be absorbed by the light absorbent and developing the second layer; and forming the flow path by removing the mold.

### BACKGROUND OF THE INVENTION

1. Field of the Invention

The present invention relates to a manufacturing method of a liquid discharge head, and more particularly, to a manufacturing method of an ink jet recording head for performing recording by discharging ink onto a recording medium.

2. Description of the Related Art

As an example of a liquid discharge head, there is an ink jet recording head applied to an ink jet recording method of performing recording by discharging ink onto a recording medium. A method of manufacturing such an ink jet recording head is disclosed in, for example, Japanese Patent Application Laid-Open No. 2005-125619.

In the manufacturing method disclosed in Japanese Patent Application Laid-Open No. 2005-125619, a positive-type photosensitive resin layer stacked on a substrate is exposed and developed to form a mold of an ink flow path, a coating layer for coating the mold is provided, and the coating layer is exposed to form a discharge port. In addition, in order to suppress an influence of light reflection during the exposure for forming the discharge port on the shape of the discharge port, an upper layer of the stacked positive-type photosensitive resin contains an ultraviolet absorbent.

In the manufacturing method disclosed in Japanese Patent Application Laid-Open No. 2005-125619, in a case where the stacked positive-type photosensitive resin layer having the layer containing the ultraviolet absorbent is exposed, in consideration of the influence of the ultraviolet absorbent that absorbs irradiated light on resolution, the amount of the ultraviolet absorbent to be added needs to be adjusted. In recent years, the diameter of the flow path of the ink jet recording head has been reduced. Accordingly, when the mold of the flow path with the reduced diameter is to be formed, more precise adjustment and management of the amount of the ultraviolet absorbent are needed. Therefore, a manufacturing load is increased.

### SUMMARY OF THE INVENTION

In order to solve the above-mentioned problem, an object of the invention is to provide a manufacturing method of a liquid discharge head, capable of reducing a load during manufacturing and obtaining a discharge port having a desired shape with good precision.

According to an aspect of the invention, there is provided a manufacturing method of a liquid discharge head having a liquid flow path which communicates with a discharge port for discharging liquid, including; providing a first layer made of a first photosensitive resin on a substrate, forming a mold of the flow path from the first layer by exposing a part of the first layer and developing the first layer; applying a light absorbent to a surface of the mold, providing a second layer made of a second photosensitive resin to coat the mold applied with the light absorbent, forming an opening that is to be the discharge port in the second layer by exposing a part of the second layer with light having a wavelength that can be absorbed by the light absorbent and developing the second layer, and forming the flow path by removing the mold.

According to the aspect of the invention, a desired shape of the discharge port can be obtained with good precision under a low load.

Further features of the present invention will become apparent from the following description of exemplary embodiments with reference to the attached drawings.

### BRIEF DESCRIPTION OF THE DRAWINGS

FIG. 1 is a schematic view of an ink jet recording head manufactured by a method according to the invention.

FIG. 2 is a cross-sectional view of the ink jet recording head in which an ink supply member is disposed, which is manufactured by the method according to the invention.

FIGS. 3A, 3B, 3C, 3D, 3E, 3F and 3G are diagrams illustrating processes of the manufacturing method of the ink jet recording head according to the invention.

FIG. 4 is a cross-sectional view of a second layer during exposure in the method according to the invention.

### DESCRIPTION OF THE EMBODIMENTS

Exemplary embodiments of the present invention will now be described in detail in accordance with the accompanying drawings. In addition, in the following description, an ink jet recording head is exemplified as a liquid discharge head. However, the invention is not limited thereto, and the liquid discharge head can be applied to various industrial fields including circuit formation as well as printing fields.

In addition, in the following description, like elements having the same function are denoted by like reference numerals in the figure, and detailed description thereof will be omitted.

Ink Jet Recording Head

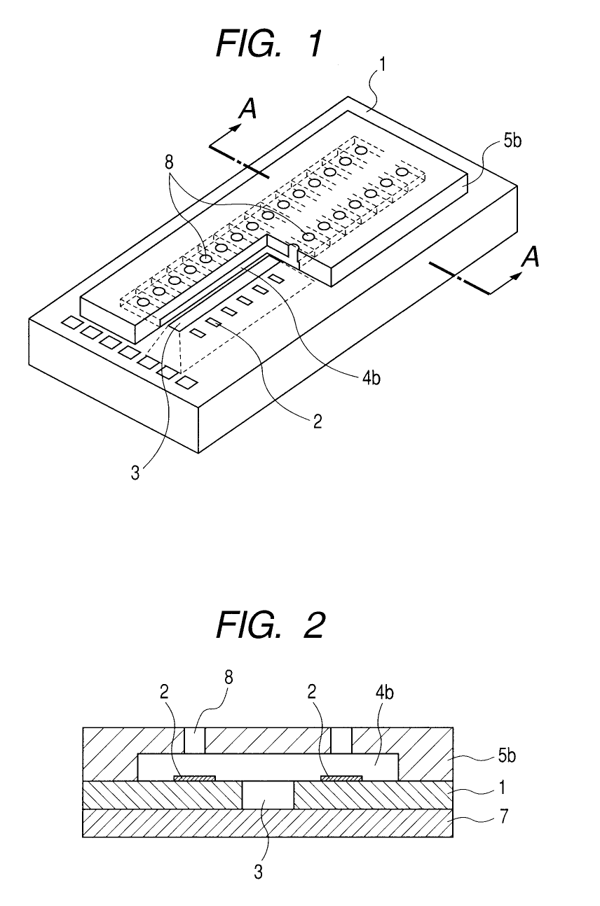

An example of an ink jet recording head manufactured by a method according to the invention is illustrated in FIG. 1.

The ink jet recording head illustrated in FIG. 1 includes, on a substrate 1 having a plurality of energy generating elements 2 for discharging ink, an ink discharge port 8 for discharging ink, an ink flow path 4b which communicates with the ink discharge port 8 and stores the ink, an ink flow path formation member 5b for forming the ink discharge port 8 and the ink flow path 4b. In addition, an ink supply port 3 for supplying ink to the ink flow path 4b is provided in the substrate 1. FIG. 2 is a cross-sectional view illustrating the ink jet recording head configured by attaching the ink supply member 7 to a rear surface of the substrate 1 of the ink jet recording head illustrated in FIG. 1, the ink jet recording head being taken along the line A-A of FIG. 1.

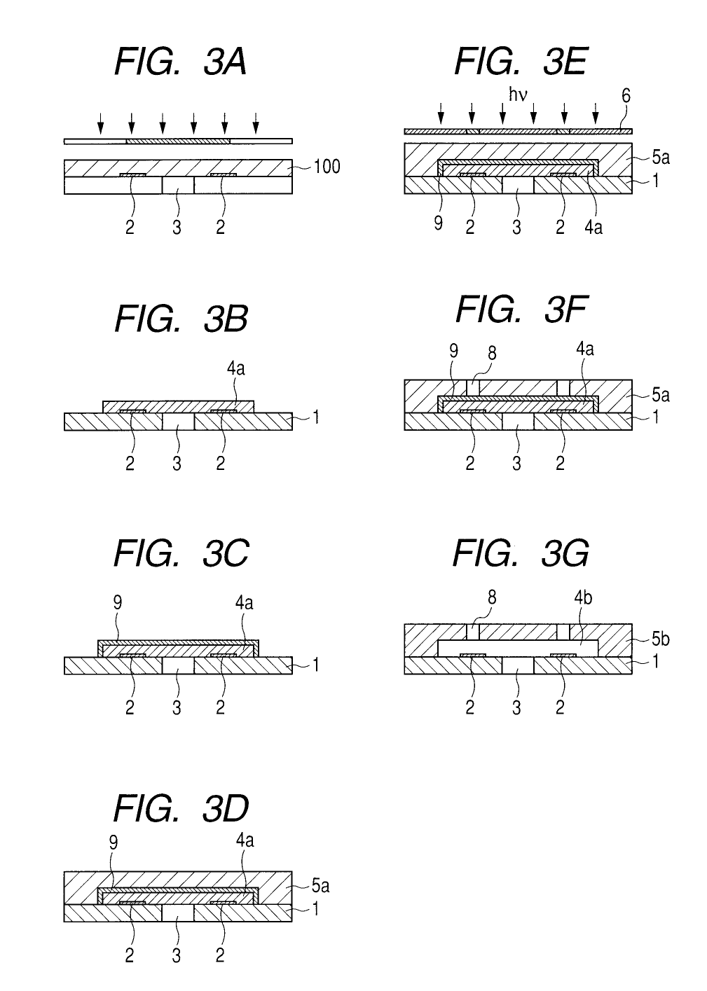

Hereinafter, each process will be described with reference to FIGS. 3A to 3G. FIGS. 3A to 3G are process diagrams illustrating the cross-section taken along the line A-A of FIG. 1.

Process 1

First, as illustrated in FIG. 3A, on the substrate 1 provided with the energy generating element 2 and the supply port 3, a first photosensitive resin layer 100 including a first photosensitive resin is formed. In addition, the supply port 3 may not be formed in this process. A surface of the substrate 1 is provided with a metal film made of silicon nitride, silicon oxide, silicon carbide, or Ta as a protective film of the energy generating element 2.

As the first photosensitive resin included in the first photosensitive resin layer 100, there are a negative-type photosensitive resin and a positive-type photosensitive resin. A material of which absorbance for absorbing ultraviolet rays used to expose a second layer 5a described layer is low may be used. In the following description, as the photosensitive resin layer 100, a positive-type photosensitive resin layer containing a positive-type photosensitive resin is exemplified. In addition, a material having sensitivity to an active energy beam having a wavelength shorter than that of ultraviolet rays, for example, an excimer laser such as an ArF laser or a KrF laser, or a Deep UV light may be used. For example, polymethyl isoprophenyl ketone that can be exposed by the Deep UV light may be employed. In a method of forming the first photosensitive resin layer 100, for example, a photosensitive resin is dissolved in a suitable solvent, and the solution is applied by spin coating. Thereafter, pre-baking is performed to form the first photosensitive resin layer 100. A thickness of the first photosensitive resin layer 100 may be a desired height of the ink flow path, and may be in the range of, for example, 5 to 25 μm although it is not particularly limited thereto.

Process 2

Next, a flow path pattern 4a which is the mold of the ink flow path is formed by patterning the first photosensitive resin layer 100 (FIG. 3B).

In a method of patterning the first photosensitive resin layer 100, the active energy beam to which the positive-type photosensitive resin is sensitive is irradiated onto the first photosensitive resin layer 100 via a mask so as to be exposed and patterned. Thereafter, development is performed using a solvent that dissolves the first photosensitive resin layer 100, and rinsing is performed thereon, thereby forming the flow path pattern 4a which is the mold of the ink flow path.

Process 3

Next, an ultraviolet absorbent is added to a surface layer of the flow path pattern 4a such that the surface layer of the flow path pattern 4a is reformed to a layer 9 (hereinafter, simply referred to as a reformed layer) containing the ultraviolet absorbent (FIG. 3C).

According to the invention, as the surface layer of the flow path pattern 4a is reformed to the layer 9 containing the ultraviolet absorbent, a reflecting light of the active energy beam including ultraviolet rays from the substrate 1 is absorbed during the exposure of the second layer 5a described layer, thereby suppressing deformation of the ink discharge port.

Since the ultraviolet absorbent is applied after forming the pattern 4a, the ultraviolet absorbent does not have an effect during the forming of the pattern 4a from the first photosensitive resin layer 100. Therefore, when a kind or an amount of a compound used for the ultraviolet absorbent is set, factors needed for forming the pattern 4a do not need to be considered. Accordingly, a degree of freedom to select the kind of the compound used for the ultraviolet absorbent is increased, and a degree of freedom to set the amount of the compound is widened, thereby reducing a manufacturing load.

As the ultraviolet absorbent, any material that can absorb ultraviolet rays used for the exposure of the second layer 5a described later may be used. In addition, in a case where an active energy beam having a wavelength sensitive to the positive-type photosensitive resin of the flow path pattern 4a is irradiated during removal of the flow path pattern 4a, a material that is less likely to absorb the active energy beam may be used. For example, when the ultraviolet ray used for the exposure of the second layer 5a is an i-line, general ultraviolet absorbents having absorption of the i-line such as benzophenone derivatives, benzoate derivatives, and benzotriazole derivatives may be used. Otherwise, for example, anthracene derivatives may be used.

As the benzophenone derivatives, for example, 2,3′,3,4′-tetrahydroxybenzophenone, 2-hydroxy-4-methoxybenzophenone, 2,4-dihydroxybenzophenone, 2,3,4-trihydroxybenzophenone, 2,3,4,4′-tetrahydroxybenzophenone, 2-hydroxy-4-octoxybenzophenone, or 3-aminobenzophenone may be used.

As the benzoate derivatives, bis(2,2,6,6-tetramethyl-4-piperidyl)sebacate, or bis(1,2,2,6,6-pentamethyl-4-piperidyl)sebacate may be used. As the benzotriazole derivatives, 2-(2-hydroxy-5-t-butylphenyl)-2H-benzotriazole, or 2-(5-methyl-2-hydroxyphenyl)benzotriazole may be used. As the anthracene derivatives, 1,8,9-trihydroxyanthracene, or 1,8-bis(hydroxymethyl)anthracene may be used. One or more kinds selected from the group including the above-mentioned derivatives may be used in combination.

In a method of reforming the surface layer of the flow path pattern 4a to the layer 9 containing the ultraviolet absorbent, for example, an application solution obtained by dissolving the ultraviolet absorbent in an application solvent is applied by spin coating on the flow path pattern 4a and the substrate 1. Thereafter, heating and cleaning are performed thereon.

As the application solvent, those that can appropriately dissolve the surface of the flow path pattern 4a during the application of the application solution may be used. For example, when polymethyl isoprophenyl ketone is used for the flow path pattern 4a, as well as propylene glycol monomethyl ether, ethyl lactate, or cyclohexanone may be used. With the application solution, the surface of the flow path pattern 4a impregnates the application solution, so that the ultraviolet absorbent can be fixed to the surface of the flow path pattern 4a, and the deformation of the ink discharge port can be prevented. As the application solution, one or more kinds of materials may be used in combination.

When a solvent that does not dissolve the flow path pattern 4a is used as the application solvent, the ultraviolet absorbent is not fixed to the surface of the flow path pattern 4a, so that there is no effect of suppressing the deformation of the ink discharge port. For example, when polymethyl isoprophenyl ketone is used for the flow path pattern 4a, alcohols such as ethanol and isopropyl alcohol may be used. In addition, a mixed solvent obtained by mixing the application solvent that dissolves the flow path pattern 4a with an application solvent that does not dissolve it may be used as long as the mixed solvent can dissolve the flow path pattern 4a. Particularly, in a case where a kind of application solvent has high solubility and the single use thereof has an adverse effect on the shape of the flow path pattern 4a, the application solvent may be mixed with the application solvent that does not dissolve the flow path pattern 4a to adjust solubility.

An amount of the ultraviolet absorbent contained in the application solution may be in the range of 0.5 to 5 mass% when 2,3′,3,4′-tetrahydroxybenzophenone and propylene glycol monomethyl ether are used as the ultraviolet absorbent and the application solvent, respectively. When the amount thereof is equal to or greater than 0.5, an effect of preventing the deformation of the ink discharge port can be obtained more reliably. In terms of stability (precipitation) of the application solution, the amount thereof may be equal to or less than 5 mass %. Of course, the amount of the ultraviolet absorbent contained in the application solution is determined depending on a type of the ultraviolet absorbent used and a type of the application solvent and is not limited thereto. In addition, an additive used for stably dissolving the ultraviolet absorbent in the application solution may be added.

Process 4

Next, the second layer 5a is formed of a second photosensitive resin on the flow path pattern 4a containing the reformed layer 9 and the substrate 1 (FIG. 3D).

As a material of the second layer 5a, a material of which sensitivity to a predetermined wavelength is different from that of the first layer 100 is used. In addition, the photosensitive resin having a photosensitivity to a different wavelength range of ultraviolet rays from that of the material used for the flow path pattern 4a may be used. In the case where the flow path pattern 4a of the first layer 100 is made of the positive-type photosensitive resin, the second layer 5a may be made of a negative-type photosensitive resin in terms of the wavelength region. In a method of forming the second layer 5a, for example, a solution obtained by dissolving the material of the second layer 5a in a suitable solvent is applied to the flow path pattern 4a and the substrate 1 by spin coating, thereby forming the second layer 5a. When the solvent is used, a solvent that does not dissolve the flow path pattern 4a is selected and used. An upper limit of a thickness of the second layer 5a is not particularly limited as long as developing performance of the ink discharge port is not damaged.

Process 5

Next, an active energy beam such as the ultraviolet rays having the photosensitive wavelength is exposed to the second layer 5a (FIG. 3E), and by performing development thereon, the ink discharge port 8 is formed (FIG. 3F).

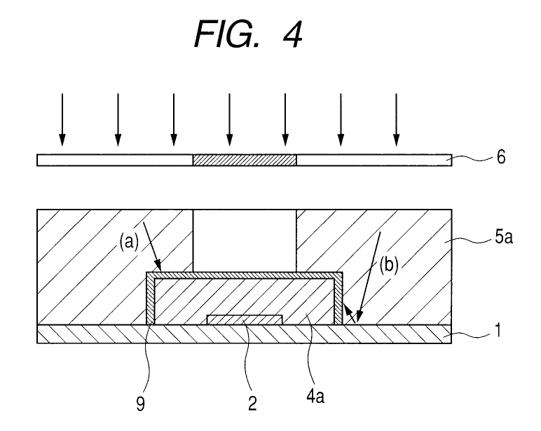

Here, FIG. 4 is a cross-sectional view of the state illustrated in FIG. 3E in a cross-section perpendicular to the line A-A of FIG. 1. According to the method of the invention, light beams illustrated in FIG. 3A can be suppressed from reaching the surface of the substrate 1 when the second layer 5a is exposed. Since the ultraviolet absorbent is provided on a side surface of the flow path pattern 4a, light beams reflecting from the surface of the substrate 1 illustrated in FIG. 3B can be reliably absorbed. The light beams reflecting from the surface of the substrate 1 can be set not to correspond to an adjacent discharge port formation portion or the closest ink discharge port formation portion of the resin layer 5a.

As described above, according to the invention, since the surface layer of the flow path pattern 4a is reformed to the layer 9 including the ultraviolet absorbent, the reflecting light of the active energy beam including the ultraviolet ray of the photosensitive wavelength from the substrate 1 is absorbed, thereby suppressing the deformation of the ink discharge port. In the method of forming the ink discharge port 8, the i-line is irradiated onto the second layer 5a via a mask 6. Thereafter, heating, developing, and rinsing are performed thereon, thereby forming the ink discharge port 8. A width of the ink discharge port 8 may be suitably set depending on a size of an ink droplet to be discharged. Here, the i-line is light having a center wavelength of 365 nm. A half width of the i-line is about 5 nm.

In addition, in the manufacturing method according to the invention, as the second layer 5a and the flow path pattern 4a coexist, small build-up of scum occurs at a lower portion of the ink discharge port as developing scum of the second layer 5a during the patterning of the ink discharge port. Due to the existence of the small build-up of scum, the ink jet recording head may produce a deteriorated print result particularly when discharging extremely small liquid droplets. In this case, alkaline ultraviolet absorbents such as benzoate derivatives or benzotriazole derivatives, or alkaline ultraviolet absorbents such as aminobenzophenone as benzophenone derivatives may be used. Accordingly, due to the forming of the ink discharge port pattern, cationic polymerization of the coexisting portions of the second layer 5a and the flow path pattern 4a can be suppressed, thereby suppressing the generation of the scum.

Process 6

Next, the ink flow path 4b is formed by removing the flow path pattern 4a (FIG. 3G).

As a method of removing the flow path pattern 4a, there is a method of immersing the substrate into the solvent that can dissolve the flow path pattern 4a so as to be removed. In addition, as needed, in the wavelength region that is not absorbed by the ultraviolet absorbent, the flow path pattern 4a may be exposed by the photosensitive active energy beam to enhance solubility. Thereafter, electrical bonding is performed to drive the energy generating element 2. In addition, the ink supply member 7 for supplying ink is connected, thereby completing the ink jet recording head.

The ink jet recording head according to the invention may be mounted in a printer, a copying machine, a facsimile having a communication system, a device such as a word processor having a printer unit, and an industrial recording apparatus having multiple processing devices. In addition, by using the ink jet recording head according to the invention, recording may be performed on various types of recording media such as paper, thread, fiber, leather, metal, plastic, glass, wood, and ceramics.

Hereinafter, examples of the invention will be described, however, the invention is not limited by the examples.

### Example 1

First, as illustrated in FIG. 3A, a blast mask was covered on the silicon substrate 1 provided with the thermoelectric transducer 2 (a heater made of WSiN) as the energy generating element, and sandblasting was performed to form the ink supply port 3 for supplying ink. In addition, an insulating film is formed on the heater, and a protective film of Ta is formed thereon.

Next, polymethyl isoprophenyl ketone (brand name: “ODUR-1010” manufactured by Tokyo Ohka Kogyo Co., Ltd) as the positive-type photosensitive resin was applied on the silicon substrate 1 by spin coating. Then, pre-baking was performed at 120° C. for six minutes. Additionally, pattern exposure (Deep UV light at an exposure intensity of 14 J/cm²) was performed to form the flow path pattern 4a using a Deep UV exposing device (brand name “UX-3000” manufactured by Ushio Inc.). Thereafter, development was performed using methyl isobutyl ketone, and rinsing was performed using IPA. Accordingly, the flow path pattern 4a was formed (FIG. 3B). In addition, the thickness of the flow path pattern 4a was 10 μm.

Next, a polyethylene glycol monomethyl ether solution containing 1 mass % of 2,3′,3,4′-tetrahydroxybenzophenone, which is the ultraviolet absorbent, was applied on the flow path pattern 4a and the silicon substrate 1 by spin coating. Thereafter, pre-baking was performed thereon at 90° C. for three minutes, and cleaning was performed thereon by pure water. Accordingly, the surface layer of the flow path pattern 4a was reformed to the layer 9 containing the ultraviolet absorbent (FIG. 3C).

Next, the following resin composition 1 was dissolved in a xylene-mixed solvent at a density of 50 mass %. This solution was applied on the flow path pattern 4a and the silicon substrate 1 by spin coating to form the second layer 5a (FIG. 3D). In addition, the thickness of the second layer 5a on the flow path pattern 4a was 10 μm.

Resin Composition 1

EHPE-3150 (brand name, manufactured by Daicel Chemical Industries. Ltd.) 100 pts.mass
A-187 (brand name, manufactured by Dow Corning Toray Co. Ltd) 5 pts.mass
SP-172 (brand name, manufactured by Adeka Corporation) 1.5 pts.mass

Next, exposure (i-line at an exposure intensity of 4000 J/m²) was performed on the second layer 5a via the mask 6 by an i-line stepper exposing device (i5, manufactured by Canon Inc.) (FIG. 3E). In this example, φ8 μm of the ink discharge pattern was formed. After the exposure, baking (PEB) was performed thereon at 90° C. for four minutes. Next, development was performed using methyl isobutyl ketone to form the ink discharge port 8 (FIG. 3F). In addition, at that time point, the flow path pattern 4a was not completely developed and still had remained.

Since a plurality of the same or different ink jet recording heads was arranged on the silicon substrate 1, in this process, the silicon substrate 1 was cut by a dicer to obtain individual ink jet recording heads. Here, as described above, since the flow path pattern 4a had remained, the residue (waste) that occurs during the cutting could be prevented from being incorporated into the head.

Exposure (Deep UV light at an exposure intensity of 27 J/cm²) was performed again on the ink jet recording heads obtained as described above by the Deep UV exposing device (brand name “UX-3000” manufactured by Ushio Inc.). Thereafter, the ink jet recording head was immersed into methyl lactate by irradiating ultrasonic waves to elute the flow path pattern 4a (FIG. 3G).

Next, the second layer 5a was completely hardened by heating the ink jet recording head at 200° C. for one hour to form the ink flow path formation member 5b. Last, the ink supply member 7 was attached to the rear surface of the silicon substrate 1 provided with the ink supply port 3, thereby completing the ink jet recording head.

### Example 2

The ink jet recording head was manufactured under the same conditions as Example 1 except that bis(2,2,6,6-tetramethyl-4-piperidyl)sebacate (manufactured by Ciba Japan) was used as the ultraviolet absorbent. The evaluation result is shown in Table 1.

### Example 3

The ink jet recording head was manufactured under the same conditions as Example 1 except that 2-(2-hydroxy-5-t-butylphenyl)-2H-benzotriazole (manufactured by Ciba Japan) was used as the ultraviolet absorbent. The evaluation result is shown in Table 1.

### Example 4

The ink jet recording head was manufactured under the same conditions as Example 1 except that 3-aminobenzophenone (manufactured by Tokyo Chemical Industry Co., Ltd.) was used as the ultraviolet absorbent.

### Example 5

The ink jet recording head was manufactured under the same conditions as Example 1 except that ethyl lactate was used as the application solvent used for applying the ultraviolet absorbent, and the manufactured ink jet recording head was evaluated.

### Example 6

The ink jet recording head was manufactured under the same conditions as Example 1 except that a mixed solvent of propylene glycol monomethyl ether (50 mass %) and ethanol (50 mass %) was used as the application solvent used for applying the ultraviolet absorbent.

### Comparative Example 1

The ink jet recording head was manufactured under the same conditions as Example 1 except that the ultraviolet absorbent layer 7 was not formed.

Printing Quality Evaluation

The ink jet recording head manufactured in the examples was mounted in a recording apparatus. Using an ink made of purity/diethylene glycol/isopropyl alcohol/lithium acetate/black pigment food black 2 at a ratio of 79.4/15/3/0.1/2.5, printing was performed in a condition to print ruled lines and dots. Printing quality was evaluated using the following references.

A: there is no deterioration

B: deterioration is slightly shown but there is no problem

C: deterioration is shown

Evaluation of Shape of Ink Discharge Port

A surface shape and a cross-sectional shape of the discharge port were observed for the ink jet recording head manufactured in the examples. The shape of the ink discharge port was evaluated using the following references.

A: precisely circular shape

B: there is slight deviation from the precisely circular shape

C: deformation is shown

The evaluation result is arranged and shown in Table 1.

TABLE 1

| | Ultraviolet Absorbent Application Solution | | | Shape Of Ink |
|---|---|---|---|---|
| | | Application | Printing | Discharge |
| | Ultraviolet Absorbent | Solution | Quality | Port |
| Example 1 | 2,3′,3,4′- | Propylene glycol | A | A |
| | tetrahydroxybenzophenone | monomethyl ether | | |
| Example 2 | Bis(2,2,6,6-tetramethyl- | Propylene glycol | A | A |
| | 4-piperidyl)sebacate | monomethyl ether | | |
| Example 3 | 2-(2-hydroxy-5-t- | Propylene glycol | A | A |
| | butylphenyl)-2H- | monomethyl ether | | |
| | benzotriazole | | | |
| Example 4 | 3-aminobenzophenone | Propylene glycol | A | A |
| | | monomethyl ether | | |
| Example 5 | 2,3′,3,4′- | Ethyl lactate | A | A |
| | tetrahydroxybenzophenone | | | |
| Example 6 | 2,3′,3,4′,- | Propylene glycol | B | B |
| | tetrahydroxybenzophenone | monomethyl ether | | |
| | | 50% + ethanol 50% | | |
| Comparative | None | None | C | C |
| Example 1 | | | | |

The ink jet recording head manufactured in the examples enables stable printing, and a printed result exhibits high quality. Particularly, the application solution using propylene glycol monomethyl ether or ethyl lactate shows excellent performance. In addition, in Example 4, with regard to an edge portion on the flow path side of the discharge port, tailing of an inner wall of the discharge port rarely occurred, and the inner wall was formed to be substantially perpendicular to a bottom portion of the discharge part when viewed in a cross-section of the discharge port. It is thought that this is because when cationic polymerization occurred in the second layer, amino groups of aminobenzophenone trapped parts of cationically active species and suppressed excessive cationic polymerization. The ink jet recording head manufactured in Comparative Example 1 produced a deteriorated printed result. It is thought that this is because light used for the exposure during the forming of the discharge port reflects toward the substrate and an undesirable shape of the discharge port was formed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-090117, filed on Apr. 2, 2009, which is hereby incorporated by reference herein in its entirety.

What is claimed is:

1. A manufacturing method of a liquid discharge head having a liquid flow path which communicates with a discharge port for discharging liquid, comprising:
providing a first layer consisting of a first photosensitive resin on a substrate;
forming a mold of the flow path from the first layer by exposing a part of the first layer and developing the first layer;
applying a light absorbent to a surface of the mold;
providing a second layer consisting of a second photosensitive resin to coat the mold applied with the light absorbent;
forming an opening that is to be the discharge port in the second layer by exposing a part of the second layer with light having a wavelength that can be absorbed by the light absorbent and developing the second layer; and
forming the flow path by removing the mold.

2. The manufacturing method according to claim 1,
wherein the first photosensitive resin is a positive-type photosensitive resin, and
the second photosensitive resin is a negative-type photosensitive resin.

3. The manufacturing method according to claim 2,
wherein the first photosensitive resin contains polymethyl isoprophenyl ketone, and
the light absorbent contains benzophenone compounds.

4. The manufacturing method according to claim 1, wherein the light absorbent is applied to a surface of the mold by allowing a solution containing the light absorbent to permeate into the surface of the mold.

5. The manufacturing method according to claim 3, wherein the light absorbent is aminobenzophenone.

6. The manufacturing method according to claim 1, wherein the light absorbent is applied to a side surface of the mold.

7. The manufacturing method according to claim 3, wherein exposure for forming the opening is performed on the second layer with an i-line.

8. The manufacturing method according to claim 1, wherein a film of Ta is provided on a surface of the substrate.
